(19) United States
(12) Patent Application Publication
(10) Pub. No.: US 2025/0216425 A1
(43) Pub. Date: Jul. 3, 2025

(54) POWER DETECTION DEVICE

(71) Applicant: RichWave Technology Corp., Taipei City (TW)

(72) Inventor: Yi-Fong Wang, Taipei City (TW)

(73) Assignee: RichWave Technology Corp., Taipei City (TW)

(21) Appl. No.: 18/977,976

(22) Filed: Dec. 12, 2024

Related U.S. Application Data
(60) Provisional application No. 63/615,807, filed on Dec. 29, 2023.

(30) Foreign Application Priority Data
Nov. 21, 2024 (TW) 113144832

(51) Int. Cl. G01R 21/14; G01R 21/00

(52) U.S. Cl. CPC G01R 21/14; G01R 21/005

(57) ABSTRACT

A power detection device includes a set of power detectors, a set of voltage-to-current converters, a temperature compensation circuit, a current-to-voltage converter, and a level shifter. The set of power detectors is used to generate a set of power detection voltages. The set of voltage-to-current converters are coupled to the set of power detectors to generate a set of power detection currents according to the set of power detection voltages. The temperature compensation circuit is used to generate a temperature compensation current. The current-to-voltage converter is coupled to the set of voltage-to-current converters and the temperature compensation circuit to accumulate the set of power detection currents and the temperature compensation current to generate a summed current, and convert the summed current into a summed voltage. The level shifter is coupled to the current-to-voltage converter, and is used to receive the summed voltage to generate an output power voltage.

### CROSS REFERENCE TO RELATED APPLICATION

This application claims the benefit of U.S. Provisional Application No. 63/615,807, filed on Dec. 29, 2023 and Taiwan application serial no. 113144832, filed on Nov. 21, 2024. The content of the application is incorporated herein by reference.

### TECHNICAL FIELD

The invention relates to a radio frequency circuits, and specifically, to a power detection device.

### BACKGROUND

A power detection device is an electronic circuit used to detect the power of amplifier input/output signals. The power detection device is often used in wireless communications, audio equipment and radio frequency transmission. Power detection devices are often implemented using transistors or diodes. However, the performance of transistors and diodes (such as threshold voltage or output current) are affected by temperature changes, leading to variations in the output power detection signal.

### SUMMARY

According to one embodiment of the invention, a power detection device includes a set of power detectors, a set of voltage-to-current converters, a temperature compensation circuit, a current-to-voltage converter, and a level shifter. The set of power detectors is used to generate a set of power detection voltages according to an input signal. The set of voltage-to-current converters is coupled to the set of power detectors to generate a set of power detection currents according to the set of power detection voltages. The temperature compensation circuit includes a set of compensation diodes and/or a set of compensation transistors and is used to generate a temperature compensation current according to a temperature. The current-to-voltage converter is coupled to the set of voltage-to-current converters and the temperature compensation circuit to accumulate the set of power detection currents and the temperature compensation current to generate a summed current, and convert the summed current into a summed voltage. The level shifter is coupled to the current-to-voltage converter, and is used to receive the summed voltage to generate an output power voltage.

### BRIEF DESCRIPTION OF THE DRAWINGS

FIG. 1 is a block diagram of a power detection device according to an embodiment of the invention.

FIG. 2 is a signal diagram of the set of power detectors in FIG. 1.

FIG. 3 is a circuit schematic diagram of the set of power detectors in FIG. 1.

FIG. 4 is a circuit schematic diagram of a set of power detectors according to an embodiment of the invention.

FIG. 5 is a circuit schematic diagram of a set of power detectors according to another embodiment of the invention.

FIG. 6 is a circuit schematic diagram of the set of voltage-to-current converters, temperature compensation circuit, and current-to-voltage converter in FIG. 1.

FIG. 7 is a signal diagram of the set of voltage-to-current converters in FIG. 1.

FIG. 8 is another circuit schematic diagram of the set of voltage-to-current converters, temperature compensation circuit, and current-to-voltage converter in FIG. 1.

FIG. 9 is another circuit schematic diagram of the set of voltage-to-current converters, temperature compensation circuit, and current-to-voltage converter in FIG. 1.

FIG. 10 is a circuit schematic diagram of the envelope detector in FIG. 1.

FIG. 11 is another circuit schematic diagram of the envelope detector in FIG. 1.

FIG. 12 is another circuit schematic diagram of the envelope detector in FIG. 1.

FIG. 13 is a block diagram of a power amplifier according to an embodiment of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

In various embodiment of the invention, the transistor may be a bipolar junction transistor (BJT) or a metal oxide semiconductor field-effect transistor (MOSFET). If the transistor is a bipolar junction transistor, the control terminal may be a base, the first terminal may be a collector, and the second terminal may be an emitter. If the transistor is a metal oxide semiconductor field-effect transistor, the control terminal may be a gate, the first terminal may be a drain, and the second terminal may be a source.

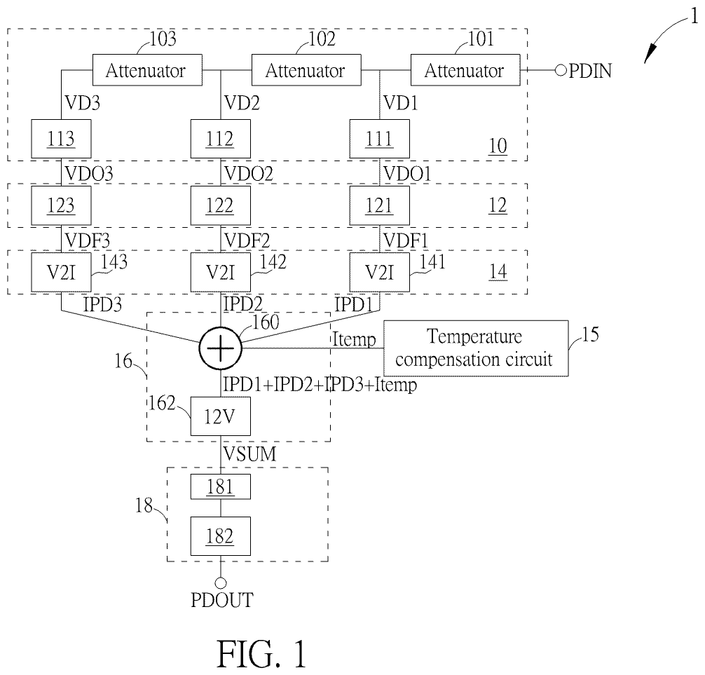

FIG. 1 is a block diagram of a power detection device 1 according to an embodiment of the invention. The power detection device 1 may receive an input signal PDIN, and detect the amplitude of the input signal PDIN to generate an output power signal PDOUT that remains substantially unchanged or only varies slightly with temperature. The input signal PDIN may be an alternating current (AC) voltage, especially a radio frequency (RF) voltage. The output power signal PDOUT may be a direct current (DC) voltage corresponding to the power of the input signal PDIN. The input signal PDIN may be the input signal or the output signal of a power amplifier.

The power detection device 1 may include a set of power detectors 10, a set of harmonic filters 12, a set of voltage-to-current converters (V2I) 14, a temperature compensation circuit 15, a current-to-voltage converter (I2V) 16, and an envelope detector 18. The set of power detectors 10, the set of harmonic filters 12 and the set of voltage-to-current converters 14 may be coupled in sequence. The set of voltage-to-current converters 14 and temperature compensation circuit 15 may be coupled to the current-to-voltage converter 16. The envelope detector 18 may be coupled to the current-to-voltage converter 16. The set of power detectors 10 may generate a set of power detection voltages (VDO1, VDO2, VDO3) according to the input signal PDIN. The set of harmonic filters 12 may all be resistor-capacitor (RC) low-pass filters used to selectively filter out harmonic frequencies in the set of power detection voltages (VDO1, VDO2, VDO3) to generate a set of filtered voltages (VDF1, VDF2, VDF3) to improve signal quality. The set of voltage-to-current converters 14 may generate a set of power detection currents (IPD1, IPD2, IPD3) according to the set of filtered voltages (VDF1, VDF2, VDF3) after filtering out harmonic frequencies. The temperature compensation circuit 15 may generate a temperature compensation current Itemp according to the temperature. The temperature compensation circuit 15 may include a set of compensation diodes and/or a set of compensation transistors. The current-to-voltage converter 16 may include a current node 160 and a current-to-voltage conversion circuit (I2V) 162. The current node 160 may accumulate the set of power detection currents (IPD1, IPD2, IPD3) and the temperature compensation current Itemp to generate a summed current (IPD1+IPD2+IPD3+Itemp). The current-to-voltage conversion circuit 162 may convert the summed current (IPD1+IPD2+IPD3+Itemp) into a summed voltage VSUM. The envelope detector 18 may receive the summed voltage VSUM to generate the output power voltage PDOUT. The envelope detector 18 may include a level shifter 181 and a low-pass filter 182. The level shifter 181 may include a set of level shift transistors to adjust the level of the summed voltage VSUM, and the low-pass filter 182 may filter out the AC component in the summed voltage VSUM to generate the DC output power voltage PDOUT.

The components in the power detection device 1 may be implemented using bipolar junction transistor (BJT) or metal oxide semiconductor field-effect transistor (MOSFET). However, the electrical characteristics of BJTs and MOSFETs are affected by temperature. Therefore, the power detection device 1 uses the temperature compensation circuit 15 to ensure that the output power signal PDOUT remains stable or only slightly varies with temperature changes. In other words, the temperature compensation circuit 15 may enable the summed voltage VSUM to have a negative temperature coefficient, thereby compensating for the temperature variation of the level shifter 181 in the envelope detector 18 to reduce the temperature variation of the output power signal PDOUT. For example, both the set of compensation transistors in the temperature compensation circuit 15 and the set of level shift transistors in the level shifter 181 may be BJTs. Consequently, the PN junctions of the set of compensation diodes and/or the set of compensation transistors and the set of level shift transistors are made of identical materials, allowing the set of compensation diodes and/or the set of compensation transistors to generate the temperature compensation current Itemp through the PN junctions. Since the PN junctions of the set of compensation diodes and/or the set of compensation transistors and the set of level shift transistors are made of identical materials (such as the same n+/p doping composition and concentration) and have the same temperature coefficient, the temperature compensation current Itemp generated by the set of compensation transistors may offset the temperature change in the set of level shift transistors. In some embodiments, the temperature compensation current Itemp may have a positive temperature coefficient and the summed voltage VSUM may have a negative temperature coefficient.

The set of power detectors 10 may include N power detectors to detect power in segments to improve the linearity of the detected power, N being a positive integer greater than 1. The N power detectors may generate N power detection voltages according to the input signal PDIN. Each power detector may include an attenuator and a power detection circuit, and may determine the power detection voltage generated by each power detector. Correspondingly, the set of harmonic filters 12 may include N harmonic filters, each harmonic filter is coupled to a corresponding power detector in the N power detectors, and can filter out harmonic components (for example, the first harmonic component sin(ωt) and the second harmonic component sin(2ωt), ω represents the fundamental frequency, and t represents time.) in the power detection voltage of the corresponding power detector to generate a filtered voltage. The filtered voltage may include a DC component and/or a baseband component. The set of voltage-to-current converters 14 may include N voltage-to-current converters. Each voltage-to-current converter is coupled to a corresponding power detector in the N power detectors through a corresponding harmonic filter in the N harmonic filters, and may generate a power detection current according to at least the filtered voltage of the corresponding harmonic filter. For example, if N=3, the set of power detectors 10 may include three power detectors, the set of harmonic filters 12 may include harmonic filters 121 to 123, and the set of voltage-to-current 14 may include voltage-to-current converters 141 to 143, as shown in FIG. 1.

In FIG. 1, the first power detector may include an attenuator 101 and a power detection circuit 111 to generate a power detection voltage VDO1. The second power detector may include an attenuator 102 and a power detection circuit 112 to generate the power detection voltage VDO2. The third power detector may include an attenuator 103 and a power detection circuit 113 to generate the power detection voltage VDO3. The attenuators 101 to 103 may include resistors and/or capacitors to adjust the attenuation of the input signal PDIN and control the impedance matching the signal source. The attenuators 101 to 103 may receive the input signal PDIN and may have different attenuation quantities to generate attenuated signals VD1 to VD3. In one embodiment, the attenuators 101 to 103 may sequentially attenuate the input signal PDIN, and the signal strengths of the attenuated signals VD1 to VD3 may sequentially increase with respect to the input signal PDIN. The power detection circuits 111 to 113 may respectively perform half-wave rectification on the attenuated signals VD1 to VD3 to generate power detection voltages VDO1 to VDO3. When the attenuated signals VD1, VD2 and/or VD3 are respectively smaller than the linear operating ranges of the power detection circuits 111, 112 and/or 113, the power detection voltages VDO1, VDO2 and/or VDO3 may be maintained at a low level. When the attenuated signals VD1, VD2 and/or VD3 respectively fall within the linear operating ranges of the power detection circuits 111, 112 and/or 113, the power detection voltages VDO1, VDO2 and/or VDO3 may increase linearly as the attenuated signals VD1, VD2 and/or VD3 increase. However, if the attenuated signals VD1, VD2 and/or VD3 respectively exceed the linear operating ranges of the power detection circuits 111, 112 and/or 113, the power detection voltages VDO1, VDO2 and/or VDO3 may be maintained at a high level.

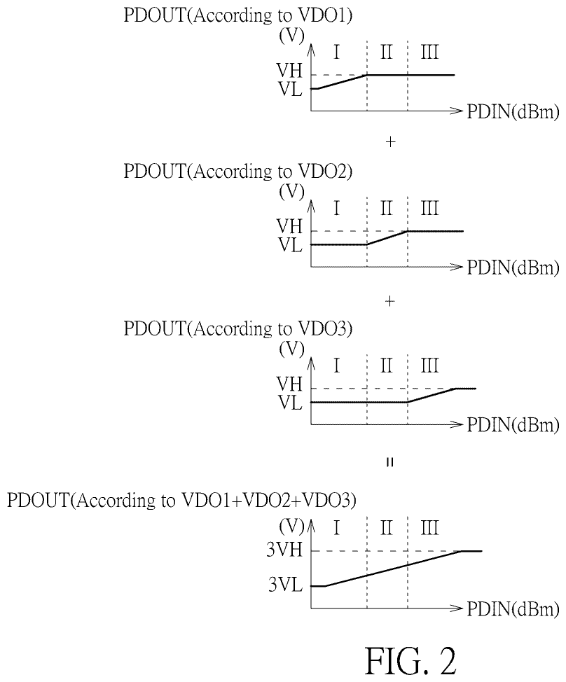

FIG. 2 is a signal diagram of the set of power detectors 10. The horizontal axis represents the power of the input signal PDIN, in decibel-milliwatts (dBm), and the vertical axis represents the output power voltage PDOUT associated with the power detection voltages VDO1 to VDO3 and the summed voltage (VDO1+VDO2+VDO3), in volts (V). In the operating power range, the output power voltage PDOUT may be linearly related to the power of the input signal PDIN.

When the power of the input signal PDIN is within a low power range I, the output power voltage PDOUT associated with the power detection voltage VDO1 may linearly increase from the low level VL to the high level VH as the power of the input signal PDIN increases, while the output power voltage PDOUT associated with the detection voltages VDO2 and VDO3 may be maintained at the low level VL. Consequently, the output power voltage PDOUT component associated with the summed voltage (VDO1+VDO2+VDO3) may linearly increase from 3VL to (2VL+VH) as the power detection voltage VDO1 increases in the low power range I. When the power of the input signal PDIN is within the mid-power range II, the output power voltage PDOUT associated with the power detection voltage VDO1 may be maintained at a high level VH, the output power voltage PDOUT associated with the power detection voltage VDO2 may linearly increase from the low level VL to the high level VH as the power of the input signal PDIN increases, and the output power voltage PDOUT associated with the power detection voltage VDO3 may be maintained at the low level VL. Consequently, the output power voltage PDOUT associated with the summed voltage (VDO1+VDO2+VDO3) may linearly increase from (2VL+VH) to (VL+2VH) as the power detection voltage VDO2 increases in the mid-power range II. When the power of the input signal PDIN is within the high power range III, the output power voltage PDOUT associated with the power detection voltages VDO1 and VDO2 may be maintained at the high level VH, and the output power voltage PDOUT associated with the power detection voltage VDO3 may linearly increase from the low level VL to the high level VH as the power of the input signal PDIN increases. Consequently, the output power voltage PDOUT associated with the summed voltage (VDO1+VDO2+VDO3) may linearly increase from (VL+2VH) to 3VH as the power detection voltage VDO3 increases in the high power range III. Therefore, the power detection circuits 111, 112 and 113 may realize a wide range of linear power detection within their respective linear operating ranges.

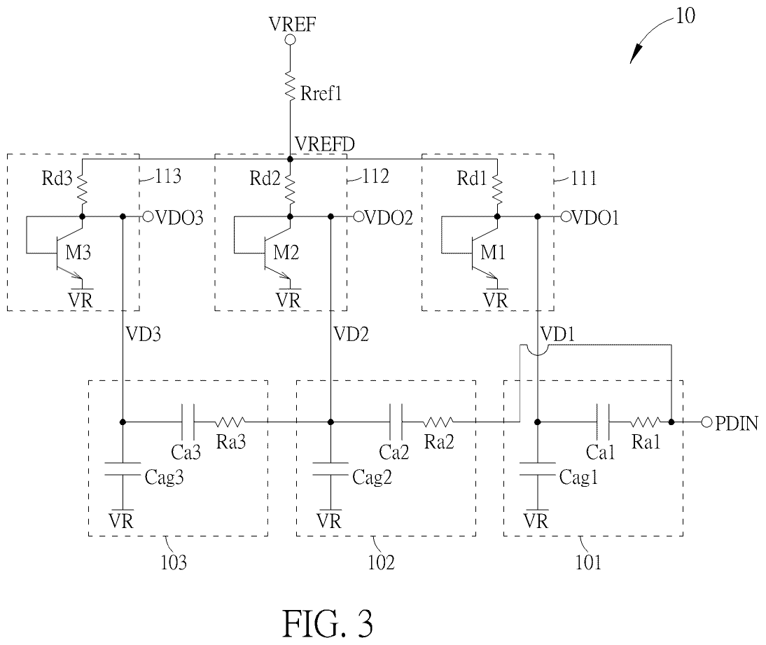

In one embodiment, at least two of the attenuators 101 to 103 may be coupled in parallel and at least two attenuators may be coupled in series, as shown in FIG. 3. FIG. 3 is a circuit schematic diagram of the set of power detectors 10. The set of power detectors 10 may include attenuators 101 to 103, power detection circuits 111 to 113, and a resistor Rref1. The resistor Rref1 includes a first terminal and a second terminal. The first terminal of the resistor Rref1 is coupled to the second reference voltage terminal to receive a reference voltage VREF; and the second terminal of the resistor Rref1 is used to provide a voltage VREFD. The attenuators 102 and 103 may be coupled in series, and the attenuator 101 may be coupled in parallel with the attenuators 102 and 103 which are coupled in series. The attenuator 101 may be coupled to the power detection circuit 111, the attenuator 102 may be coupled to the power detection circuit 112, the attenuator 103 may be coupled to the power detection circuit 113, and the power detection circuits 111 to 113 may be coupled to the first terminal of the resistor Rref1. In some embodiments, the resistor Rref1 may be omitted, and the power detection circuits 111 to 113 may be coupled to the second reference voltage terminal to receive the reference voltage VREF. The attenuator 101 may receive the input signal PDIN and generate the attenuated signal VD1, the attenuator 102 may receive the input signal PDIN and generate the attenuated signal VD2, and the attenuator 103 may receive the attenuated signal VD2 and generate the attenuated signal VD3. The power detection circuit 111 may receive the attenuated signal VD1 and generate the power detection voltage VDO1, the power detection circuit 112 may receive the attenuated signal VD2 and generate the power detection voltage VDO2, and the power detection circuit 113 can receive the attenuated signal VD3 and generate the power detection voltage VDO3.

The attenuator 101 may include a resistor Ra1, and capacitors Ca1 and Cag1. The resistor Ra1 includes a first terminal and a second terminal, and the first terminal of the resistor Ra1 is used to receive the input signal PDIN. The capacitor Ca1 includes a first terminal and a second terminal, and the first terminal of the capacitor Ca1 is coupled to the second terminal of the resistor Ra1. The capacitor Cag1 includes a first terminal and a second terminal. The first terminal of the capacitor Cag1 is coupled to the second terminal of the capacitor Ca1 to generate the attenuated signal VD1; and the second terminal of the capacitor Cag1 is coupled to the first reference voltage terminal to receive a reference voltage VR. The reference voltage VR may be a ground voltage, such as 0V.

The attenuator 102 may include a resistor Ra2, and capacitors Ca2 and Cag2. The resistor Ra2 includes a first terminal and a second terminal, and the first terminal of the resistor Ra2 is used to receive the input signal PDIN. The capacitor Ca2 includes a first terminal and a second terminal, and the first terminal of the capacitor Ca2 is coupled to the second terminal of the resistor Ra2. The capacitor Cag2 includes a first terminal and a second terminal. The first terminal of the capacitor Cag2 is coupled to the second terminal of the capacitor Ca2 to generate the attenuated signal VD2; and the second terminal of the capacitor Cag2 is coupled to the first reference voltage terminal to receive the reference voltage VR.

The attenuator 103 may include a resistor Ra3, and capacitors Ca3 and Cag3. The resistor Ra3 includes a first terminal and a second terminal, and the first terminal of the resistor Ra3 is coupled to the second terminal of the capacitor Ca2. The capacitor Ca3 includes a first terminal and a second terminal, and the first terminal of the capacitor Ca3 is coupled to the second terminal of the resistor Ra3. The capacitor Cag3 includes a first terminal and a second terminal, the first terminal of the capacitor Cag3 is coupled to the second terminal of the capacitor Ca3 to generate the attenuated signal VD3; the second terminal is coupled to the first reference voltage terminal to receive the reference voltage VR.

The resistors Ra1 to Ra3 may attenuate the input signal PDIN and increase the input impedance of the power detection device 1. The capacitors Ca1 to Ca3 may remove the DC offset error between the attenuators 101 to 103 and allow only the AC component to pass, thus ensuring the accuracy of the signals. The capacitors Cag1 to Cag3 may attenuate the AC component of the input signal PDIN and adjust the input impedance of the power detection device 1. In some embodiments, the attenuators 101 to 103 may be coupled in series. Therefore, the attenuators 101 to 103 may attenuate the input signal PDIN to generate the attenuated signals VD1 to VD3 with different attenuation quantities. At the same time, the attenuators 101 to 103 may employ resistive elements and capacitive elements to optimize the real part and the imaginary part of the input signal PDIN respectively, thereby increasing the error vector magnitude (EVM) of the power amplifier, thereby improving performance and efficiency.

The resistor Rref1 includes a first terminal coupled to the second reference voltage terminal to receive the reference voltage VREF; and a second terminal to provide the voltage VREFD. The reference voltage VREF may be greater than the reference voltage VR, for example, the reference voltage VREF may be 3V.

The power detection circuit 111 may include a resistor Rd1 and a transistor M1. The resistor Rd1 includes a first terminal and a second terminal. The first terminal of the resistor Rd1 is coupled to the second terminal of the resistor Rref1; and the second terminal of the resistor Rd1 is coupled to the first terminal of the capacitor Cag1 to receive the attenuated signal VD1 and generate the power detection voltage VDO1. The transistor M1 includes a control terminal, a first terminal and a second terminal. The first terminal of the transistor M1 is coupled to the control terminal of the transistor M1 and the second terminal of the resistor Rd1; and the second terminal of the transistor M1 is coupled to the first reference voltage terminal to receive the reference voltage VR.

The power detection circuit 112 may include a resistor Rd2 and a transistor M2. The resistor Rd2 includes a first terminal and a second terminal. The first terminal of the resistor Rd2 is coupled to the first terminal of the resistor Rd1, and the second terminal of the resistor Rd2 is coupled to the first terminal of the capacitor Cag2 to receive the attenuated signal VD2 and generate the power detection voltage VDO2. The transistor M2 includes a control terminal, a first terminal and a second terminal. The first terminal of the transistor M2 is coupled to the control terminal of the transistor M2 and the second terminal of the resistor Rd2, and the second terminal of the transistor M2 is coupled to the first reference voltage terminal to receive the reference voltage VR.

The power detection circuit 113 may include a resistor Rd3 and a transistor M3. The resistor Rd3 includes a first terminal and a second terminal. The first terminal of the resistor Rd3 is coupled to the first terminal of the resistor Rd1, the second terminal of the resistor Rd3 is coupled to the first terminal of the capacitor Cag3 to receive the attenuated signal VD3 and generate the power detection voltage VDO3. The transistor M3 includes a control terminal, a first terminal and a second terminal. The first terminal of the transistor M3 is coupled to the control terminal of the transistor M3 and the second terminal of the resistor Rd3, and the second terminal of the transistor M3 is coupled to the first reference voltage terminal to receive the reference voltage VR.

The transistor M1 to M3 may be a bipolar junction transistor (BJT) or a metal oxide semiconductor field-effect transistor (MOSFET). The transistors M1 to M3 are disposed in the form of diodes. When the attenuated signal VD1, VD2 or VD3 is less than the threshold voltage (such as 0.7V) of the transistor M1, M2 or M3, the transistor M1, M2 or M3 may be turned off, and the power detection voltage VDO1, VDO2 or VDO3 may be equal to the attenuated signal VD1, VD2 or VD3. When the attenuated signal VD1, VD2 or VD3 is greater than or equal to the threshold voltage of the transistor M1, M2 or M3, the transistor M1, M2 or M3 may be turned on, and the power detection voltage VDO1, VDO2 or VDO3 may be equal to the threshold voltage of the transistor M1, M2 or M3. Therefore the transistors M1 to M3 may be regarded as half-wave rectifiers to allow the negative half-cycle to pass while blocking the positive half-cycle. In some embodiments, the transistors M1 to M3 may also be configured as half-wave rectifiers, allowing the positive half-cycle to pass while blocking the negative half-cycle.

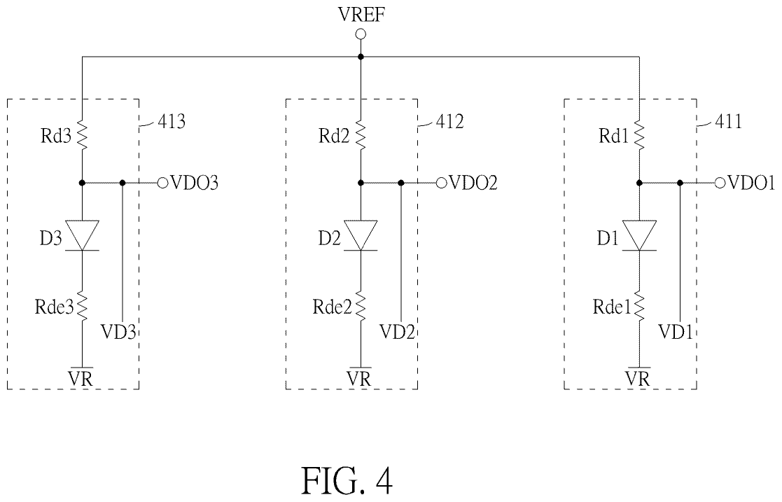

FIG. 4 is a circuit schematic diagram of a set of power detectors. The set of power detection circuits may include power detection circuits 411 to 413 to replace the power detection circuits 111 to 113 in FIG. 3. The resistor Rref1 may be removed from the set of power detectors 10 in FIG. 3, allowing the power detection circuits 411 to 413 to directly receive the reference voltage VREF.

The power detection circuit 411 may include a resistor Rd1, a diode D1 and a resistor Rde1. The resistor Rd1 includes a first terminal and a second terminal. The first terminal of the resistor Rd1 is coupled to the second reference voltage terminal to receive the reference voltage VREF, and the second terminal of the resistor Rd1 is configured to receive the attenuated signal VD1 and generate the power detection voltage VDO1. The diode D1 includes a first terminal (anode) and a second terminal (cathode). The first terminal of the diode D1 is coupled to the second terminal of the resistor Rd1. The resistor Rde1 includes a first terminal and a second terminal. The first terminal of the resistor Rde1 is coupled to the second terminal of the diode D1, and the second terminal of the resistor Rde1 is coupled to the first reference voltage terminal to receive the reference voltage VR.

The power detection circuit 412 may include a resistor Rd2, a diode D2 and a resistor Rde2. The resistor Rd2 includes a first terminal and a second terminal. The first terminal of the resistor Rd2 is coupled to the second reference voltage terminal to receive the reference voltage VREF, and the second terminal of the resistor Rd2 is configured to receive the attenuated signal VD2 and generate the power detection voltage VDO2. The diode D2 includes a first terminal (anode) and a second terminal (cathode). The first terminal of the diode D2 is coupled to the second terminal of the resistor Rd2. The resistor Rde2 includes a first terminal and a second terminal. The first terminal of the resistor Rde2 is coupled to the second terminal of the diode D2, and the second terminal of the resistor Rde2 is coupled to the first reference voltage terminal to receive the reference voltage VR.

The power detection circuit 413 may include a resistor Rd3, a diode D3 and a resistor Rde3. The resistor Rd3 includes a first terminal and a second terminal. The first terminal of the resistor Rd3 is coupled to the second reference voltage terminal to receive the reference voltage VREF, and the second terminal of the resistor Rd3 is configured to receive the attenuated signal VD3 and generate the power detection voltage VDO3. The diode D3 includes a first terminal (anode) and a second terminal (cathode). The first terminal of the diode D3 is coupled to the second terminal of the resistor Rd3. The resistor Rde3 includes a first terminal and a second terminal. The first terminal of the resistor Rde3 is coupled to the second terminal of the diode D3, and the second terminal of the resistor Rde3 is coupled to the first reference voltage terminal to receive the reference voltage VR.

The power detection circuits 411 to 413 operate similarly to the power detection circuits 111 to 113. The power detection circuits 411 to 413 may respectively perform half-wave rectification on the attenuated signals VD1 to VD3 to generate power detection voltages VDO1 to VDO3. The resistors Rd1 to Rd3 may control the bias points of diodes D1 to D3 respectively. The resistors Rde1 to Rde3 may be used as emitter degradation resistors to increase the linearity of the power of the input signal PDIN to the power detection voltages VDO1 to VDO3 respectively. In one embodiment, the second terminals of the diodes D1 to D3 are directly coupled to the reference voltage VR.

In the power detection circuit 411, the resistor Rd1, the diode D1 and the resistor Rde1 may be regarded as a voltage divider. The voltage at the first terminal of the diode D1 may be a divided voltage of the reference voltage VREF, which is determined by the resistance values of the resistors Rd1 and Rde1 and the threshold voltage of the diode D1 (for example, 0.7V). In this embodiment, the voltage Vdiv at the first terminal of the diode D1 may be expressed by Formula (1):

$$Vdiv 1 = ( VREF - THD 1 ) * Rde 1 / ( Rde 1 + Rd 1 ) + THD 1 \qquad Formula ( 1 )$$

Wherein Vdiv1 is the voltage at the first terminal of the diode D1; VREF is the reference voltage;
Rde1 is the resistance value of the resistor Rde1;
Rd1 is the resistance value of the resistor Rd1; and
THD1 is the threshold voltage of the diode D1.

When the attenuated signal VD1 is less than the divided voltage Vdiv1, the diode D1 may be turned off, and the power detection voltage VDO1 may be equal to the attenuated signal VD1. When the attenuated signal VD1 is greater than or equal to the divided voltage Vdiv1, the diode D1 may be turned on, and the power detection voltage VDO1 may be equal to the divided voltage Vdiv1. The operation of the power detection circuits 412 and 413 may be similar to that of the power detection circuit 411, and will not be describe again here. According to the foregoing, the power detection circuits 411 to 413 may be regarded as half-wave rectifiers allowing the negative half-cycle to pass while blocking the positive half-cycle. In some embodiments, the power detection circuits 411 to 413 may also be configured as half-wave rectifiers, allowing the positive half-cycle to pass while blocking the negative half-cycle. The threshold voltages of the diodes D1 to D3 may change with temperature, for example, decrease as the temperature increases. For example, the temperature coefficient of the threshold voltage of the diodes D1 to D3 may be −2 mV/degrees Celsius, that is, when the temperature rises by 1 degree Celsius, the threshold voltage of diodes D1 to D3 will decrease by 2 millivolts.

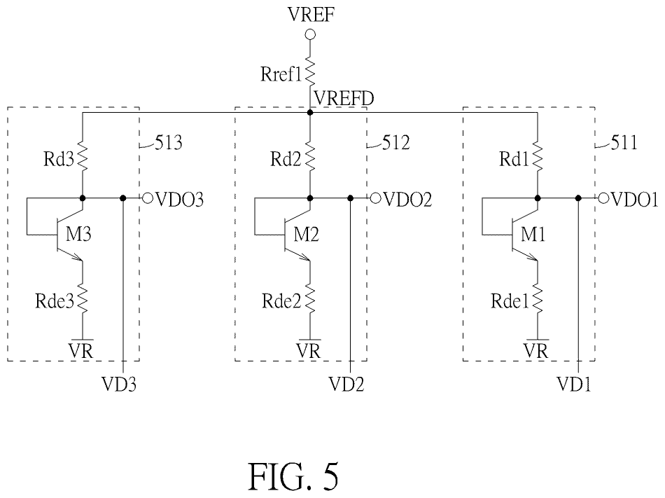

FIG. 5 is another circuit schematic diagram of a set of power detectors. The set of power detection circuits may include power detection circuits 511 to 513 to replace the power detection circuits 111 to 113 in FIG. 3. The resistor Rref1 includes a first terminal and a second terminal. The first terminal of the resistor Rref1 is coupled to the second reference voltage terminal to receive the reference voltage VREF; the second terminal of the resistor Rref1 is configured to provide the voltage VREFD.

The transistors M1 to M3 of the power detection circuits 511 to 513 may be configured in the form of diodes to replace the diodes D1 to D3 of the power detection circuits 411 to 413. The circuit configurations and operations of the power detection circuits 511 to 513 may be similar to those of the power detection circuits 411 to 413 and will not be described again here.

Please refer to FIG. 1, the harmonic filter 12 may include N harmonic filters, and each harmonic filter is coupled to a corresponding power detector in the N power detectors.

The harmonic filter 121 may include a first harmonic resistor and a first harmonic capacitor. The first harmonic resistor receives the power detection voltage VDO1, and the first harmonic capacitor is coupled between the first harmonic resistor and the first reference voltage terminal to output the filtered voltage VDF1. The harmonic filter 121 may filter out the first and second harmonic components in the power detection voltage VDO1 to generate the filtered voltage VDF1. The filtered voltage VDF1 includes static components and variable components. The static component is equivalent to the voltage generated by the power detection circuit 111 when it is statically biased (ie, there is no input signal PDIN), while the variable component changes as the power of the input signal PDIN increases, reflecting changes in the voltage generated by the power detection circuit 111 according to the input signal PDIN.

The harmonic filter 122 may include a second harmonic resistor and a second harmonic capacitor. The second harmonic resistor receives the power detection voltage VDO2, and the second harmonic capacitor is coupled between the second harmonic resistor and the first reference voltage terminal to output the filtered voltage VDF2. The harmonic filter 122 may filter out the first and second harmonic components in the power detection voltage VDO2 to generate the filtered voltage VDF2. The filtered voltage VDF2 includes static components and variable components. The static component is equivalent to the voltage generated by the power detection circuit 112 when it is statically biased (ie, there is no input signal PDIN), while the variable component changes as the power of the input signal PDIN increases, reflecting changes in the voltage generated by the power detection circuit 112 according to the input signal PDIN.

The harmonic filter 123 may include a third harmonic resistor and a third harmonic capacitor. The third harmonic resistor receives the power detection voltage VDO3, and the third harmonic capacitor is coupled between the third harmonic resistor and the first reference voltage terminal to output the filtered voltage VDF3. The harmonic filter 123 may filter out the first and second harmonic components in the power detection voltage VDO3 to generate the filtered voltage VDF3. The filtered voltage VDF3 includes static components and variable components. The static component is equivalent to the voltage generated by the power detection circuit 113 when it is statically biased (ie, there is no input signal PDIN), while the variable component changes as the power of the input signal PDIN increases, reflecting changes in the voltage generated by the power detection circuit 113 according to the input signal PDIN. In some embodiment, the harmonic filters 121, 122, and 123 may be replaced by other suitable filters as required.

As the input signal PDIN changes, the filter voltages VDF1 to VDF3 present a piecewise continuous linear relationship in the low power range I, the medium power range II, and the high power range III. Specifically, as the power of the input signal PDIN increases, the negative DC voltage of the filter voltage VDF1/VDF2/VDF3 decreases, indicating that there is an inverse relationship between the power of the input signal PDIN and the filter voltage VDF1/VDF2/VDF3.

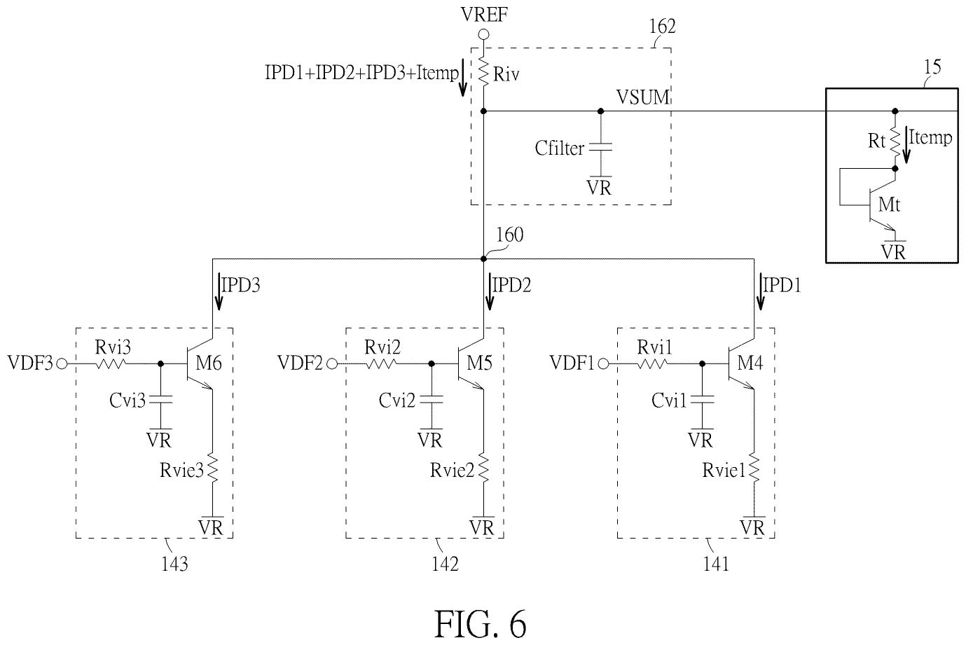

FIG. 6 is a circuit schematic diagram of the set of voltage-to-current converters 14, temperature compensation circuit 15, and current-to-voltage converter 16.

The voltage-to-current converter 141 may include a resistor Rvi1, a capacitor Cvi1, a transistor M4 and a resistor Rvie1. The resistor Rvi1 includes a first terminal and a second terminal. The first terminal of the resistor Rvi1 is coupled to the harmonic filter 121 to receive the filtered voltage VDF1. The capacitor Cvi1 includes a first terminal and a second terminal. The first terminal of the capacitor Cvi1 is coupled to the second terminal of the resistor Rvi1, and the second terminal of the capacitor Cvi1 is coupled to the first reference voltage terminal to receive the reference voltage VR. The transistor M4 includes a control terminal, a first terminal and a second terminal. The control terminal of the transistor M4 is coupled to the first terminal of the capacitor Cvi1, and the first terminal of the transistor M4 is coupled to the current node 160. The resistor Rvie1 includes a first terminal and a second terminal. The first terminal of the resistor Rvie1 is coupled to the second terminal of the transistor M4, and the second terminal of the resistor Rvie1 is coupled to the first reference voltage terminal to receive the reference voltage VR.

The voltage-to-current converter 142 may include a resistor Rvi2, a capacitor Cvi2, a transistor M5 and a resistor Rvie2. The resistor Rvi2 includes a first terminal and a second terminal. The first terminal of the resistor Rvi2 is coupled to the harmonic filter 122 to receive the filtered voltage VDF2. The capacitor Cvi2 includes a first terminal and a second terminal. The first terminal of the capacitor Cvi2 is coupled to the second terminal of the resistor Rvi2, and the second terminal of the capacitor Cvi2 is coupled to the first reference voltage terminal to receive the reference voltage VR. The transistor M5 includes a control terminal, a first terminal and a second terminal. The control terminal of the transistor M5 is coupled to the first terminal of the capacitor Cvi2, and the first terminal of the transistor M5 is coupled to the current node 160. The resistor Rvie2 includes a first terminal and a second terminal. The first terminal of the resistor Rvie2 is coupled to the second terminal of the transistor M5, and the second terminal of the resistor Rvie2 is coupled to the first reference voltage terminal to receive the reference voltage VR.

The voltage-to-current converter 143 may include a resistor Rvi3, a capacitor Cvi3, a transistor M6 and a resistor Rvie3. The resistor Rvi3 includes a first terminal and a second terminal. The first terminal of the resistor Rvi3 is coupled to the harmonic filter 123 to receive the filtered voltage VDF3. The capacitor Cvi3 includes a first terminal and a second terminal. The first terminal of the capacitor Cvi3 is coupled to the second terminal of the resistor Rvi3, and the second terminal of the capacitor Cvi3 is coupled to the first reference voltage terminal to receive the reference voltage VR. The transistor M6 includes a control terminal, a first terminal and a second terminal. The control terminal of the transistor M6 is coupled to the first terminal of the capacitor Cvi3, and the first terminal of the transistor M6 is coupled to the current node 160. The resistor Rvie3 includes a first terminal and a second terminal, the first terminal of the resistor Rvie3 is coupled to the second terminal of the transistor M6, and the second terminal of the resistor Rvie3 is coupled to the first reference voltage terminal to receive the reference voltage VR.

The resistor Rvi1 and the capacitor Cvi1, the resistor Rvi2 and the capacitor Cvi2, and the resistor Rvi3 and the capacitor Cvi3 may respectively form a low-pass filter for filtering the noise of the filter voltages VDF1 to VDF3. These filtered voltages VDF1 to VDF3 may be output to the control terminals of transistors M4 to M6 respectively. In some embodiments, the resistor Rvi1 and the capacitor Cvi1, the resistor Rvi2 and the capacitor Cvi2, and the resistor Rvi3 and the capacitor Cvi3 may be omitted from the voltage-to-current converters 141 to 143.

The voltage-to-current converters 141 to 143 in FIG. 6 respectively include emitter degradation resistors Rvie1 to Rvie3, which may be used with the set of power detection circuits in FIGS. 4 and 5. The resistors Rvie1 to Rvie3 may be used as emitter degradation resistors to respectively set the minimum voltage of the filter voltages VDF1 to VDF3. The transistor M4 to M6 may be a bipolar junction transistor (BJT) or a metal oxide semiconductor field-effect transistor (MOSFET). If the transistors M4 to M6 are BJTs, the transistors M4 to M6 may receive a bias to operate in the active region.

The voltage-current converters 141 to 143 may respectively generate power detection currents IPD1 to IPD3 according to the filtered voltages VDF1 to VDF3, as expressed in Formulas (2)-(4):

$$IPD 1 = N 4 * β * [ ( VDF 1 - VBEM 4 ) / ( N 4 * β * Rvie 1 + Rvi 1 ) ] \qquad Formula ( 2 )$$

$$IPD 2 = N 5 * β * [ ( VDF 2 - VBEM 5 ) / ( N 5 * β * Rvie 2 + Rvi 2 ) ] \qquad Formula ( 3 )$$

$$IPD 3 = N 6 * β * [ ( VDF 3 - VBEM 6 ) / ( N 6 * β * Rvie 3 + Rvi 3 ) ] \qquad Formula ( 4 )$$

Wherein IPD1 to IPD3 are the power detection currents generated by the voltage-current converters 141 to 143 respectively; N4 to N6 are the voltage to current conversion ratios of transistors M4, M5, and M6 respectively;
β (bata) is the gain of transistors M4, M5, M6;
VBEM4 to VBEM6 are the threshold voltages of transistors M4, M5, and M6 respectively;
Rvie1, Rvie2, and Rvie3 are the resistance values of resistors Rvie1, Rvie2, and Rvie3 respectively; and
Rvi1, Rvi2, and Rvi3 are the resistance values of resistors Rvi1, Rvi2, and Rvi3 respectively.

According to Formula (2), the filter voltage VDF1 and the power detection current IPD1 are positively correlated. In the low power range I, when the input signal PDIN increases, the filter voltage VDF1 may decrease accordingly, and the power detection current IPD1 may also decrease. According to Formula (3), the filter voltage VDF2 and the power detection current IPD2 are positively correlated. In the medium power range II, when the input signal PDIN increases, the filter voltage VDF2 may decrease accordingly, and the power detection current IPD2 may also decrease. According to Formula (4), the filter voltage VDF3 and the power detection current IPD3 are positively correlated. In the high power range III, when the input signal PDIN increases, the filter voltage VDF3 may decrease accordingly, and the power detection current IPD3 may also decrease.

In some embodiments, the emitter degradation resistors Rvie1 to Rvie3 may be omitted, and the power detection currents IPD1 to IPD3 may be expressed as Formulas (5)-(7):

$$IPD 1 = N 4 * β * [ ( VDF 1 - VBEM 4 ) / Rvi 1 ] \qquad Formula ( 5 )$$

$$IPD 2 = N 5 * β * [ ( VDF 2 - VBEM 5 ) / Rvi 2 ] \qquad Formula ( 6 )$$

$$IPD 3 = N 6 * β * [ ( VDF 3 - VBEM 6 ) / Rvi 3 ] \qquad Formula ( 7 )$$

The current-to-voltage conversion circuit 162 may include a resistor Riv and a capacitor Cfilter. The resistor Riv includes a first terminal and a second terminal. The first terminal of the resistor Riv is coupled to the second reference voltage terminal to receive the reference voltage VREF, and the second terminal of the resistor Riv is coupled to the current node 160 for generating the summed voltage VSUM. The capacitor Cfilter includes a first terminal and a second terminal. The first terminal of the capacitor Cfilter is coupled to the second terminal of the resistor Riv, and the second terminal of the capacitor Cfilter is coupled to the first reference voltage terminal to receive the reference voltage VR.

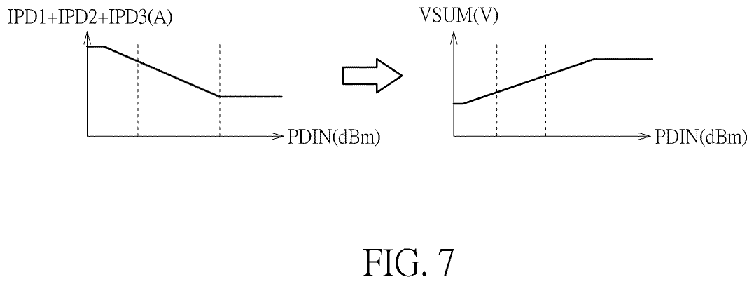

Since the power detection currents IPD1 to IPD3 all flow through the resistor Riv from the second reference voltage terminal, the summed voltage VSUM may be negatively correlated with the sum of the power detection currents IPD1 to IPD3 (IPD1+IPD2+IPD3), as shown in FIG. 7. FIG. 7 is a signal diagram of the set of voltage-to-current converters 14. The horizontal axis represents the power of the input signal PDIN in dBm, and the vertical axis represents the sum of currents (IPD1+IPD2+IPD3) in ampere (A) and the summed voltage VSUM in V. When the power of the input signal PDIN gradually increases, the sum of the power detection currents IPD1 to IPD3 (IPD1+IPD2+IPD3) may decrease accordingly, leading to a decrease in the voltage across the resistor Riv. Since the reference voltage VREF remains fixed, the summed voltage VSUM may increase accordingly.

Please refer to FIG. 6, since the power detection device 1 is implemented using BJTs and/or MOSFETs, the total current (IPD1+IPD2+IPD3) may change with temperature. The temperature compensation circuit 15 may generate a temperature compensation current Itemp to perform temperature compensation.

The temperature compensation circuit 15 includes a resistor Rt and a set of compensation transistors Mt. The resistor Rt includes a first terminal and a second terminal. The first terminal of the resistor Rt is coupled to the current-to-voltage conversion circuit 162. The set of compensation transistors Mt includes a control terminal, a first terminal and a second terminal. The control terminal and the first terminal of the set of compensation transistors Mt are coupled to the second terminal of the resistor Rt, the second terminal of the set of compensation transistors Mt is coupled to the first reference voltage terminal to receive the reference voltage VR.

The set of compensation transistors Mt may include one or more compensation transistors Mt, and each compensation transistor Mt is configured in the form of a diode. In FIG. 6, the set of compensation transistors Mt includes a compensation transistor Mt configured in the form of a diode and the threshold voltage of the compensation transistor Mt may decrease as the temperature increases. For example, the temperature coefficient of the threshold voltage of the compensation transistor Mt may be −2 mV/degrees Celsius. That is, when the temperature rises by 1 degree Celsius, the threshold voltage of the compensation transistor Mt may decrease by 2 millivolts, leading to an increase in the voltage across the resistor Rt, which subsequently results in an increase in the temperature compensation current Itemp. Since an increase in the temperature compensation current Itemp may reduce the summed voltage VSUM/output power signal PDOUT, the set of compensation transistors Mt may be regarded as a negative temperature coefficient element in the power detection device 1.

In some embodiments, the set of compensation transistors Mt may include a plurality of stacked compensation transistors Mt. The plurality of stacked compensation transistors Mt includes a first terminal and a second terminal. The first terminal of the plurality of stacked compensation transistors Mt is coupled to the second terminal of the compensation resistor Rt, and the second terminal of the plurality of stacked compensation transistors Mt is coupled to the first reference voltage terminal to receive the reference voltage VR. In detail, each compensation transistor Mt of the plurality of stacked compensation transistors Mt includes a control terminal, a first terminal and a second terminal. The first terminal of the compensation transistor Mt is coupled to the control terminal of the compensation transistor Mt, and the second terminal of the compensation transistor Mt is coupled to the first terminal of the next stacked compensation transistor Mt to form the plurality of stacked compensation transistors Mt. When the temperature rises, the total threshold voltage of the plurality of stacked compensation transistors Mt may decrease more than that of a single compensation transistor Mt, leading to an increase in the voltage across the resistor Rt, which subsequently results in a further increase in the temperature compensation current Itemp, further reducing the total voltage VSUM/output power signal PDOUT and increasing temperature compensation.

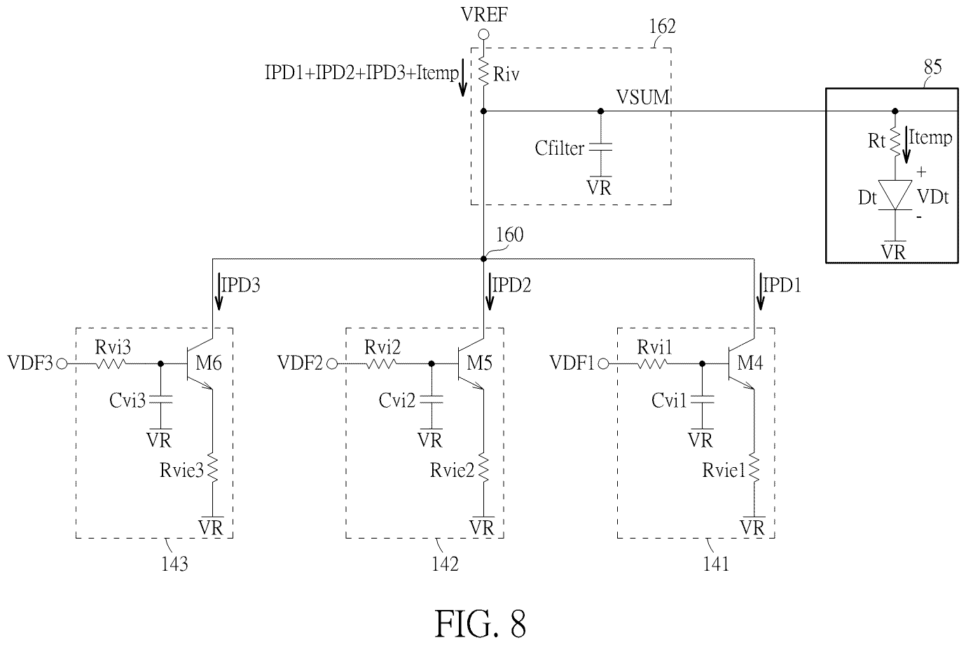

FIG. 8 is another circuit schematic diagram of the set of voltage-to-current converters 14, temperature compensation circuit 15, and current-to-voltage converter 16. The circuit elements of FIG. 8 are similar to those of FIG. 6, but a set of compensation diodes Dt are applied in the temperature compensation circuit 85 instead of the set of compensation transistors Mt in FIG. 6. The following describes the set of compensation diodes Dt in FIG. 8 in detail. For the descriptions of other circuit components, please refer to the previous paragraphs and will not be repeated here.

The set of compensation diodes Dt includes a first terminal and a second terminal. The first terminal of the set of compensation diodes Dt is coupled to the second terminal of the resistor Rt, and the second terminal of the set of compensation diodes Dt is coupled to the first reference voltage terminal to receive the reference voltage VR. In one embodiment, the first terminal of the compensation diode Dt is an anode, and the second terminal of the compensation diodes Dt is a cathode. In one embodiment, the set of compensation diodes Dt may include one or more compensation diodes Dt. In FIG. 8, the set of compensation diodes Dt includes one compensation diode Dt, and the threshold voltage VDt of the compensation diode Dt may decrease as the temperature increases. For example, the temperature coefficient of the threshold voltage VDt of the compensation diode Dt may be −2 mV/degrees Celsius. That is, when the temperature rises by 1 degree Celsius, the threshold voltage VDt of the compensation diode Dt may decrease by 2 millivolts, leading to an increase in the voltage across the resistor Rt, which subsequently results in an increase in the temperature compensation current Itemp. Since an increase in the temperature compensation current Itemp may reduce the summed voltage VSUM/output power signal PDOUT, the set of compensation diodes Dt may be regarded as a negative temperature coefficient element in the power detection device 1.

In some embodiments, the set of compensation diodes Dt may include a plurality of series-connected compensation diodes Dt. The plurality of series-connected compensation diodes Dt includes a first terminal and a second terminal. The first terminal of the plurality of series-connected compensation diodes Dt is coupled to the second terminal of the compensation resistor Rt, and the second terminal of the plurality of series-connected compensation diodes Dt is coupled to the first reference voltage terminal to receive the reference voltage VR. Each compensation diode Dt of the plurality of series-connected compensation diodes includes a first terminal (anode) and a second terminal (cathode) and the second terminal of the compensation diode Dt is coupled to the first terminal of the next compensation diode Dt to form the plurality of series-connected compensation diodes. When the temperature rises, the total threshold voltage of the plurality of series-connected compensation diodes Dt may decrease more than that of a single compensation diodes Dt, resulting in that the voltage across the resistor Rt to further increase, which in turn increases the temperature compensation current Itemp. As a result, the total voltage VSUM/output power signal PDOUT reduces further, enhancing temperature compensation.

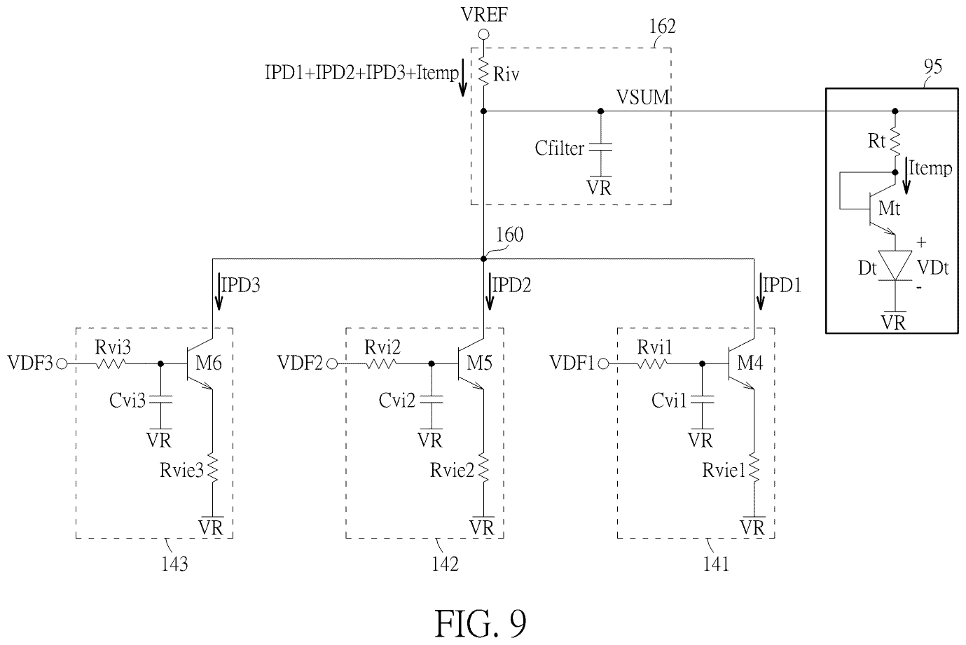

FIG. 9 is another circuit schematic diagram of the set of voltage-to-current converters 14, temperature compensation circuit 15, and current-to-voltage converter 16. The circuit components of FIG. 9 are similar to those of FIG. 6, but a set of compensation diodes Dt are further included in the temperature compensation circuit 95. The set of compensation diodes Dt and the set of compensation transistors Mt are connected in series. In FIG. 9, the set of compensation diodes Dt includes one compensation diode Dt, and the set of compensation transistors Mt may include one compensation transistor Mt. The threshold voltages of both the compensation diode Dt and the compensation transistor Mt may decrease as the temperature increases. When the temperature rises, the threshold voltages of the compensation diode Dt and the compensation transistor Mt may decrease, causing the voltage across the resistor Rt to increase, leading to an increase in the temperature compensation current Itemp, and reducing the total voltage VSUM/output power signal PDOUT. Therefore, the set of compensation transistors Mt and the set of compensation diodes Dt may be regarded as negative temperature coefficient components in the power detection device 1. In one embodiment, the set of compensation transistors Mt in FIG. 9 may be directly coupled to the set of compensation diodes Dt. In one embodiment, the compensation resistor Rt, the set of compensation diodes Dt and the set of compensation transistors Mt may be connected in series in sequence as shown in FIG. 9. In another embodiment, the order of the compensation resistor Rt, the set of compensation diodes Dt, and the set of compensation transistors Mt may be exchanged and still falls within the scope of the present patent, and will not be described again here. For other descriptions of the set of compensation diodes Dt and other circuit components, please refer to the previous paragraphs and will not be repeated here.

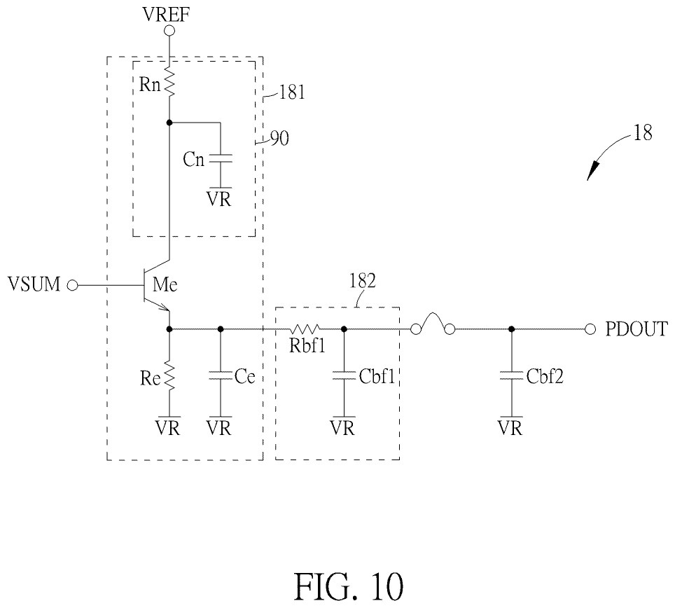

FIG. 10 is a circuit schematic diagram of the envelope detector 18. The level shifter 181 in the envelope detector 18 may include a set of level shift transistors Me, a resistor Re, and a capacitor Ce. The set of level shift transistors Me includes a control terminal, a first terminal and a second terminal. The control terminal of the set of level shift transistors Me is used to receive the summed voltage VSUM. The set of level shift transistors Me may include one or more level shift transistors Me. In FIG. 10, the set of level shift transistors Me includes one level shift transistor Me. The level shift transistor Me includes a control terminal, a first terminal and a second terminal. The control terminal of the level shift transistor Me is used to receive the summed voltage VSUM. In some embodiments, the set of level shift transistors Me may include a plurality of level shift transistors Me connected in parallel. Each level shift transistor Me includes a control terminal, a first terminal and a second terminal. The control terminal of the level shift transistor Me is used to receive the summed voltage VSUM, the first terminal of the level shift transistor Me is coupled to the first terminal of the level shift transistor Me, and the second terminal of the level shift transistor Me is coupled to the second terminal of the level shift transistor Me. The set of level shift transistors Me may receive a bias to operate in the active region. The level shifter 181 may also serve as a unity gain buffer. The level shift transistor Me may be set as a common collector to provide high input impedance and low output impedance. At the same time, the threshold voltage of the level shift transistor Me is subtracted from the summed voltage VSUM to generate a level-shifted voltage, thereby achieving level shifting and effectively isolating the circuit.

The resistor Re includes a first terminal and a second terminal. The first terminal of the resistor Re is coupled to the second terminal of the set of level shift transistors Me, and the second terminal of the resistor Re is coupled to the first reference voltage terminal to receive the reference voltage VR. The capacitor Ce includes a first terminal and a second terminal. The first terminal of the capacitor Ce is coupled to the first terminal of the resistor Re to receive the level-shifted voltage, and the second terminal of the capacitor Ce is coupled to the first reference voltage terminal to receive the reference voltage VR. The capacitor Ce may filter out ripples in the level-shifted voltage to generate a filtered signal. The filtered signal may still include envelope components. The size of the envelope component in the level-shifted voltage may be directly related to the size of the input signal PDIN. The larger the input signal PDIN is, the larger the envelope component of the level-shifted voltage is.

In some embodiments, the set of level shift transistors Me may be replaced by a set of level shift diodes. The set of level shift diodes may include a first terminal and a second terminal. The first terminal of the set of level shift diodes is used to receive the summed voltage VSUM, and the second terminal of the set of level shift diodes is coupled to the first terminal of the resistor Re and the first terminal of the capacitor Ce. The set of level shift diodes may include one or more parallel level shift diodes.

The level shifter 181 may further include a noise filter 90. The noise filter 90 includes a first terminal and a second terminal. the first terminal of the noise filter 90 is coupled to the second reference voltage terminal to receive the reference voltage VREF, and the second terminal of the noise filter 90 is coupled to the first terminal of the level shift transistor Me. The noise filter 90 includes a resistor Rn and a capacitor Cn. The resistor Rn includes a first terminal and a second terminal. The first terminal of the resistor Rn is coupled to the second reference voltage terminal to receive the reference voltage VREF, and the second terminal of the resistor Rn is coupled to the set of level shift transistors Me. The capacitor Cn includes a first terminal and a second terminal. The first terminal of the capacitor Cn is coupled to the first terminal of the set of level shift transistors Me, and the second terminal of the capacitor Cn is coupled to the first reference voltage terminal to receive the reference voltage VR. The noise filter 90 may filter out noise in the reference voltage VREF. In some embodiments, noise filter 90 may be omitted.

The low-pass filter 182 in the envelope detector 18 may include a resistor Rbf1 and a capacitor Clbf1. The resistor Rbf1 includes a first terminal and a second terminal. The first terminal of the resistor Rbf1 is used to receive the filtered signal. The capacitor Cbf1 includes a first terminal and a second terminal. The first terminal of the capacitor Cbf1 is coupled to the second terminal of the resistor Rbf1, and the second terminal of the capacitor Cbf1 is coupled to the first reference voltage terminal to receive the reference voltage VR. The low-pass filter 182 may filter out the envelope component in the level-shifted voltage to generate a DC output voltage.

The envelope detector 18 may further include an output capacitor Cbf2. The capacitor Cbf2 includes a first terminal and a second terminal. The first terminal of the capacitor Cbf2 is coupled to the first terminal of the capacitor Cbf1, the second terminal of the capacitor Cbf2 is coupled to the first reference voltage terminal to receive the reference voltage VR. The capacitor Cbf2 may receive the DC output voltage through the bonding wire and regulate the DC output voltage to generate the output power signal PDOUT.

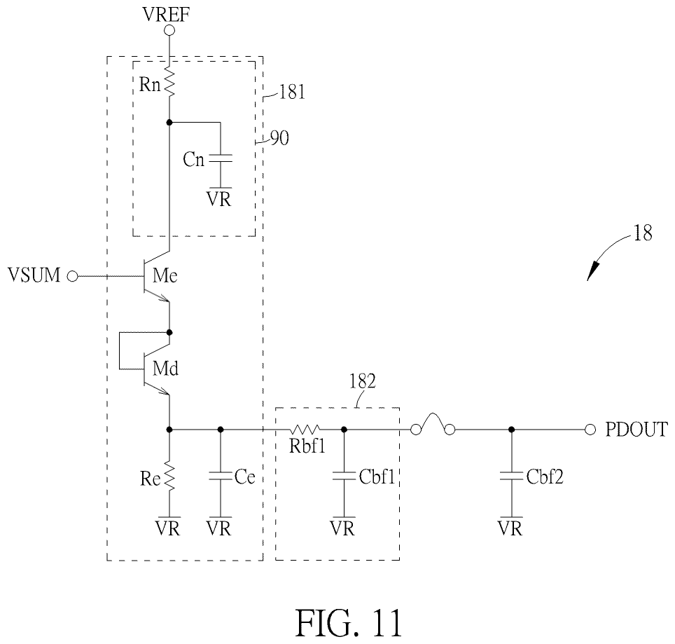

FIG. 11 is another circuit schematic diagram of the envelope detector 18 in FIG. 1. The circuit elements of FIG. 11 are similar to those of IG. 10, but the circuit elements of FIG. 11 further include at least one stacked transistor Md. The following describes a single stacked transistor Md in FIG. 11 in detail. For the descriptions of other circuit components, please refer to the previous paragraphs and will not be repeated here. The stacked transistor Md includes a control terminal, a first terminal and a second terminal. The first terminal of the stacked transistor Md is coupled to the second terminal of the set of level shift transistors Me and the control terminal of the stacked transistor Md, and the second terminal of the stacked transistor Md is coupled to The first terminal of the resistor Re. FIG. 11 only shows one stacked transistor Md, but the invention is not limited to the configuration. Those skilled in the art may change the quantity of stacked transistors Md as needed. In some embodiments, the quantity of stacked transistors Md may be greater than 1. Each stacked transistor Md includes a control terminal, a first terminal and a second terminal. The first terminal of each stacked transistor Md is coupled to the control terminal of each stacked transistor Md, and the second terminal of each stacked transistor Md is coupled to the first terminal of the next stacked transistor.

The set of level shift transistors Me and stacked transistors Md in the envelope detector 18 and the set of compensation transistors Mt in the temperature compensation circuit 15 are all BJTs. Therefore, the set of level shift transistors Me, stacked transistors Md, compensation transistor Mt and compensation diode Dt all have the same temperature coefficient, ensuring that the summed voltage VSUM has a negative temperature coefficient, thereby compensating for the temperature variation of the output power signal PDOUT.

The quantity of stacked transistors Md in the envelope detector 18 may be equal to the quantity of compensation transistors Mt or compensation diodes Dt in the temperature compensation circuit 15 minus one, or may be equal to the total quantity of compensation transistors Mt and compensation diodes Dt in the temperature compensation circuit 15 minus one. For example, if the power detection device 1 uses both the temperature compensation circuit 15 from FIG. 6 and the envelope detector 18 from FIG. 11, and the quantity of compensation transistors Mt in FIG. 6 is 2, then the quantity of stacked transistors Md in FIG. 11 may be 1. Similarly, if the power detection device 1 uses both the temperature compensation circuit 15 from FIG. 8 and the envelope detector 18 from FIG. 11, and the quantity of compensation diodes Dt in FIG. 8 is 2, then the quantity of stacked transistors Md in FIG. 11 may be 1. If the power detection device 1 uses both the temperature compensation circuit 15 from FIG. 9 and the envelope detector 18 from FIG. 11, and the total quantity of compensation transistors Mt and compensation diodes Dt in FIG. 9 is 2 (=1+1), then the quantity of stacked transistors Md in FIG. 11 may be 1. In one embodiment, the set of level shift transistors Me in FIG. 11 may be directly coupled to the stacked transistor Md. Since the quantity of PN junction devices (compensation transistor Mt and/or compensation diode Dt) in the temperature compensation circuit and PN junction devices (level shift transistors Me and stacked transistor Md) in the envelope detector 18 are the same, the power detection device 1 may achieve accurate temperature variation compensation.

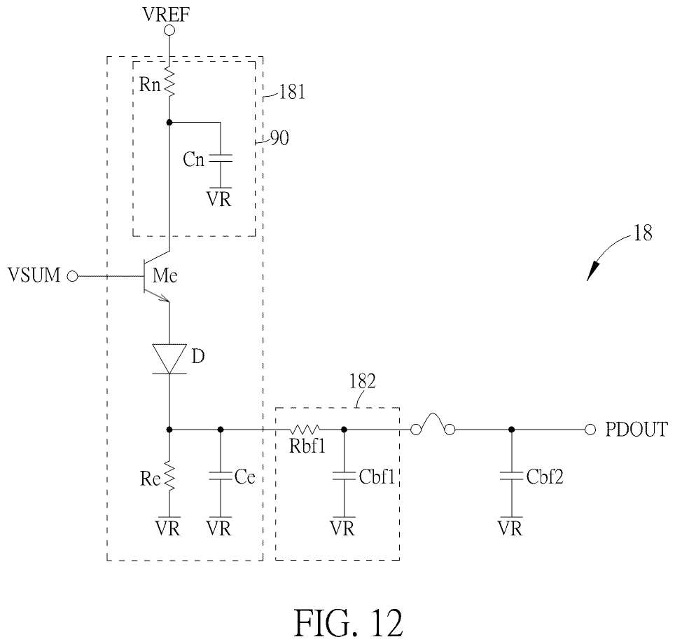

FIG. 12 is another circuit schematic diagram of the envelope detector 18 in FIG. 1. The circuit components of FIG. 12 are similar to those of FIG. 10, but the circuit components of FIG. 12 further include at least one series-connected diode D. The following describes a single series-connected diode D in FIG. 12 in detail. For explanation of other circuit components, please refer to the previous paragraphs, as the explanation will not be repeated here. The series-connected diode D includes a first terminal and a second terminal. the first terminal of the series-connected diode D is coupled to the second terminal of the set of level shift transistors Me, and the second terminal of the series-connected diode D is coupled to the first terminal of the resistor Re. FIG. 12 shows only one series-connected diode D, but the invention is not limited to the configuration. Those skilled in the art may adjust the quantity of series-connected diodes D as needed. In some embodiments, the quantity of series-connected diodes D may be greater than one. In one embodiment, the set of level shift transistors Me in the level shifter 181 may be directly coupled to the stacked transistor Md and/or the series-connected diode D.

The quantity of series-connected diodes D in the envelope detector 18 may be equal to the quantity of compensation transistors Mt or compensation diodes Dt in the temperature compensation circuit 15 minus one, or may be equal to the total quantity of compensation transistors Mt and compensation diodes Dt in the temperature compensation circuit 15 minus one. For example, if the power detection device 1 uses both the temperature compensation circuit 15 from FIG. 6 and the envelope detector 18 from FIG. 12, and the quantity of compensation transistors Mt in FIG. 6 is 2, then the quantity of series-connected diodes D in FIG. 12 may be 1. Similarly, if the power detection device 1 uses both the temperature compensation circuit 15 from FIG. 8 and the envelope detector 18 from FIG. 12, and the quantity of compensation diodes Dt in FIG. 8 is 2, then the quantity of series-connected diodes D in FIG. 12 may be 1. If the power detection device 1 uses both the temperature compensation circuit 15 from FIG. 9 and the envelope detector 18 from FIG. 12, and the total quantity of compensation transistors Mt and compensation diodes Dt in FIG. 9 is 2 (=1+1), then the quantity of series-connected diodes D in FIG. 12 may be 1. Since the quantity of PN junction devices (compensation transistor Mt and/or compensation diode Dt) in the temperature compensation circuit and PN junction devices (level shift transistors Me and series-connected diodes D) in the envelope detector 18 are the same, the power detection device 1 may achieve accurate temperature variation compensation.

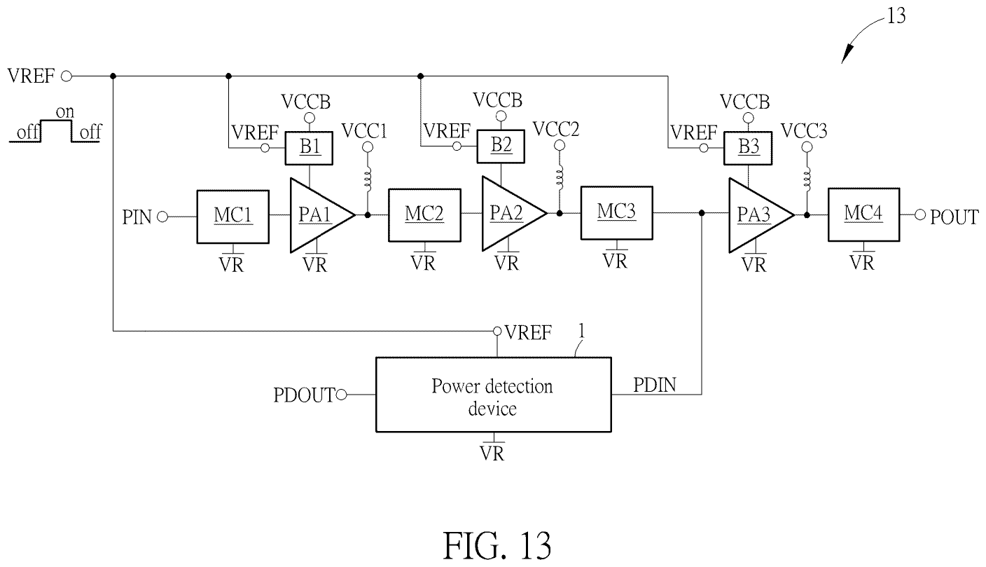

FIG. 13 is a block diagram of a power amplifier circuit 13 according to an embodiment of the invention. The power amplifier circuit 13 may receive the input signal PIN, the amplified power and generate the output signal POUT for signal transmission. The power amplifier circuit 13 may include bias circuits B1 to B3, matching circuits MC1 to MC4, and power amplifiers PA1 to PA3. The bias circuit B1 and the matching circuit MC1 may be coupled to the power amplifier PA1, the power amplifier PA1 may be coupled to the matching circuit MC2, the bias circuit B2 and the matching circuit MC2 may be coupled to the power amplifier PA2, and the power amplifier PA2 may be coupled to the matching circuit MC3, the bias circuit B3 and the matching circuit MC3 may be coupled to the power amplifier PA3, and the power amplifier PA3 may be coupled to the matching circuit MC4. The bias circuits B1 to B3 may respectively provide bias to the power amplifiers PA1 to PA3 according to the reference voltage VCCB to maintain the normal operation of the power amplifiers PA1 to PA3. The power amplifiers PA1 to PA3 may drive output signals according to the supply voltages VCC1 to VCC3 respectively. The matching circuits MC1 to MC4 may provide impedance matching between the preceding and succeeding stages, enhancing power transmission, reducing reflection losses, and preventing signal distortion and performance degradation.

The power detection device 1 may be coupled to the input terminal of the power amplifier PA3 to receive the input signal of the power amplifier PA3 as the input signal PDIN, and detect the power of the input signal PDIN to generate the output power signal PDOUT. Since the input signal PDIN is isolated by the power amplifier PA3, the impact of signal reflection due to impedance mismatch may be reduced, thereby improving the accuracy of power detection. In some embodiments, the power amplifier circuit 13 may adjust (for example, the gain) the power amplifiers PA1 to PA3 according to the output power signal PDOUT to increase the linearity of the power amplifiers PA1 to PA3. The power detection device 1 is not limited to being coupled to the input terminal of the power amplifier PA3, but can also be coupled to other terminals of the power amplifiers PA1 to PA3, such as the input terminal or the output terminal of the power amplifier PA1, the input terminal or the output terminal of the power amplifier PA2, or the output terminal of the power amplifier PA3.

The bias circuits B1 to B3 and the power detection device 1 may be coupled to the second reference voltage terminal to receive the reference signal VREF to synchronously enable or disable the power amplifier circuit 13 and the power detection device 1 according to the reference signal VREF. When the reference signal VREF is set to the conductive state (on), the amplifier circuit 13 and the power detection device 1 may be enabled simultaneously to detect the power of the input signal PDIN. When the reference signal VREF is set to the off state (off), the amplifier circuit 13 and the power detection device 1 may be disabled simultaneously, thereby reducing power loss.

The power detection device disclosed in the embodiment of the invention uses a temperature compensation circuit to perform temperature compensation to generate an output power signal that remains substantially unchanged or only varies slightly with temperature, thereby enhancing the accuracy of power detection. Furthermore, the quantity of PN junction devices in the temperature compensation circuit of the power detection device in the embodiment is the same as that in the envelope detector, ensuring accurately compensation for the temperature variation of the output power signal.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power detection device comprising:
a set of power detectors configured to generate a set of power detection voltages according to an input signal;
a set of voltage-to-current converters coupled to the set of power detectors and configured to generate a set of power detection currents according to the set of power detection voltages;
a temperature compensation circuit comprising a set of compensation diodes and/or a set of compensation transistors and configured to generate a temperature compensation current according to a temperature;
a current-to-voltage converter coupled to the set of voltage-to-current converters and the temperature compensation circuit to accumulate the set of power detection currents and the temperature compensation current to generate a summed current and convert the summed current into a summed voltage; and
a level shifter coupled to the current-to-voltage converter, comprising a set of level shift transistors, and configured to receive the summed voltage to generate an output power voltage.

2. The power detection device of claim 1, wherein PN junctions of the set of compensation diodes and/or the set of compensation transistors and the set of level shift transistors are made of identical materials, and the set of compensation diodes and/or the set of compensation transistors generate the temperature compensation current through the PN junctions.

3. The power detection device of claim 1, wherein the temperature compensation current has a positive temperature coefficient and the summed voltage has a negative temperature coefficient.

4. The power detection device of claim 1, wherein:
the temperature compensation circuit further comprises a resistor, the resistor comprising a first terminal coupled to the current-to-voltage converter; and a second terminal; and
the set of compensation diodes comprises a first terminal coupled to the second terminal of the resistor; and a second terminal coupled to a first reference voltage terminal; or
the set of compensation transistors comprises a control terminal; a first terminal coupled to the control terminal and the second terminal of the resistor; and a second terminal coupled to the first reference voltage terminal.

5. The power detection device of claim 1, wherein the set of level shift transistors of the level shifter generates a level-shifted voltage according to the summed voltage.

6. The power detection device of claim 1, wherein:
the set of level shift transistors comprises a control terminal configured to receive the summed voltage; a first terminal; and a second terminal; and
the level shifter further comprises a resistor comprising a first terminal coupled to the second terminal of the set of level shift transistors and configured to output the output power voltage; and a second terminal coupled to a first reference voltage terminal.

7. The power detection device of claim 1, wherein:
the set of level shift transistors comprises a control terminal configured to receive the summed voltage; a first terminal; and a second terminal; and
the level shifter further comprises:
a resistor comprising a first terminal configured to output the output power voltage; and a second terminal coupled to a first reference voltage terminal; and
at least one stacked transistor comprising a first terminal coupled to the second terminal of the set of level shift transistors; and a second terminal coupled to the first terminal of the resistor, wherein each of the at least one stacked transistor comprises a control terminal; a first terminal coupled to the control terminal of the each stacked transistor; and a second terminal.

8. The power detection device of claim 1, wherein:
the set of level shift transistors comprises a control terminal configured to receive the summed voltage; a first terminal; and a second terminal; and
the level shifter further comprises:
a resistor comprising a first terminal configured to output the output power voltage; and a second terminal coupled to a first reference voltage terminal; and
at least one series-connected diode comprising a first terminal coupled to the second terminal of the set of level shift transistors; and a second terminal coupled to the first terminal of the resistor.

9. The power detection device of claim 7, wherein:
the temperature compensation circuit further comprises a compensation resistor comprising a first terminal coupled to the current-to-voltage converter; and a second terminal;
the set of compensation transistors comprises a plurality of stacked compensation transistors comprising a first terminal coupled to the second terminal of the compensation resistor;
and a second terminal coupled to the first reference voltage terminal, wherein each compensation transistor of the set of compensation transistors comprises a control terminal; a first terminal coupled to the control terminal of the each compensation transistor; and a second terminal; and
a quantity of at least one stacked transistor is equal to a quantity of the plurality of stacked compensation transistors minus one.

10. The power detection device of claim 8, wherein:
the temperature compensation circuit further comprises a compensation resistor comprising a first terminal coupled to the current-to-voltage converter; and a second terminal;
the set of compensation transistors comprises a plurality of stacked compensation transistors comprising a first terminal coupled to the second terminal of the compensation resistor;
and a second terminal coupled to the first reference voltage terminal, wherein each compensation transistor of the set of compensation transistors comprises a control terminal; a first terminal coupled to the control terminal of the each compensation transistor; and a second terminal; and
a quantity of the at least one series-connected diode is equal to a quantity of the plurality of stacked compensation transistors minus one.

11. The power detection device of claim 10, wherein the plurality of stacked compensation transistors and the set of level shift transistors are both bipolar junction transistors.

12. The power detection device of claim 8, wherein:
the temperature compensation circuit further comprises a compensation resistor comprising a first terminal coupled to the current-to-voltage converter; and a second terminal;
the set of compensation diodes comprises a plurality of series-connected compensation diodes comprising a first terminal coupled to the second terminal of the compensation resistor; and a second terminal coupled to the first reference voltage terminal; and
a quantity of the at least one series-connected diode is equal to a quantity of the plurality of series-connected compensation diodes minus one.

13. The power detection device of claim 8, wherein:
the temperature compensation circuit comprises the set of compensation diodes and the set of compensation transistors coupled in series;
the temperature compensation circuit further comprises a compensation resistor comprising a first terminal coupled to the current-to-voltage converter; and a second terminal;
each compensation diode in the set of compensation diodes comprises a first terminal and a second terminal;
each compensation transistor in the set of compensation transistors comprises a control terminal; a first terminal coupled to the control terminal of the each compensation transistor; and a second terminal; and
a quantity of the at least one series-connected diode is equal to a total quantity of compensation diodes in the set of compensation diodes and compensation transistors in the set of compensation transistors minus one.

14. The power detection device of claim 1, wherein:
the set of level shift transistors comprises a plurality of level shift transistors coupled in parallel, wherein each level shift transistor comprises a control terminal configured to receive the summed voltage; a first terminal; and a second terminal; and
the level shifter further comprises a resistor, the resistor comprising a first terminal coupled to the second terminal of each level shift transistor and configured to output the output power voltage; and a second terminal coupled to a first reference voltage terminal.

15. The power detection device of claim 1, wherein:
the temperature compensation circuit further comprises resistor comprising a first terminal coupled to the current-to-voltage converter; and a second terminal; and
the set of compensation transistors comprises a plurality of compensation transistors coupled in parallel, wherein each compensation transistor comprises a control terminal; a first terminal coupled to the second terminal of the resistor and the control terminal of the each compensation transistor; and a second terminal coupled to a first reference voltage terminal.

16. The power detection device of claim 1, wherein:
the temperature compensation circuit further comprises a resistor, the resistor comprising a first terminal coupled to the current-to-voltage converter; and a second terminal; and
the set of compensation diodes comprises a plurality of compensation diodes coupled in parallel, wherein each compensation diode comprises a first terminal coupled to the second terminal of the resistor; and a second terminal coupled to a first reference voltage terminal.

17. The power detection device of claim 1, wherein the level shifter further comprises:
a noise filter comprising a first terminal coupled to a second reference voltage terminal; and a second terminal coupled to the set of level shift transistors.

18. The power detection device of claim 17, wherein the noise filer further comprises:
a resistor comprising a first terminal coupled to the second reference voltage terminal; and a second terminal coupled to the set of level shift transistors; and
a capacitor comprising a first terminal coupled to the set of level shift transistors; and a second terminal coupled to a first reference voltage terminal.

19. The power detection device of claim 1, wherein:
the set of power detectors is further coupled to a power amplifier circuit to receive the input signal from the power amplifier circuit; and
the power amplifier circuit and the set of power detectors receive a second reference voltage to synchronously disable the power amplifier circuit and the set of power detectors according to the second reference voltage.

20. The power detection device of claim 1, wherein:
the set of power detectors comprises N power detectors configured to generate N power detection voltages according to the input signal, each power detector comprising an attenuator configured to determine a power detection voltage generated by each power detector, N being an integer greater than 1, wherein at least two attenuators are coupled in parallel and at least two attenuators are coupled in series;
the set of voltage-current converters comprises N voltage-current converters, each voltage-current converter being coupled to a corresponding power detector in the N power detectors to generate a power detection current according to at least a power detection voltage of the corresponding power detector; and
the current-voltage converter is configured to accumulate the N power detection currents of the N voltage-current converters and the temperature compensation current to generate the summed current, and convert the summed current into the summed voltage.
